(19) United States
(12) Patent Application Publication
(10) Pub. No.: US 2012/0261813 A1
(43) Pub. Date: Oct. 18, 2012

(54) REINFORCED VIA FARM INTERCONNECT STRUCTURE, A METHOD OF FORMING A REINFORCED VIA FARM INTERCONNECT STRUCTURE AND A METHOD OF REDESIGNING AN INTEGRATED CIRCUIT CHIP TO INCLUDE SUCH A REINFORCED VIA FARM INTERCONNECT STRUCTURE

(75) Inventors: Felix P. Anderson, Colchester, VT (US); Timothy H. Daubenspeck, Colchester, VT (US); Jeffrey P. Gambino, Westford, VT (US); Donald R. Letourneau, Winooski, VT (US); Thomas L. McDevitt, Underhill, VT (US)

(73) Assignee: International Business Machines Corporation, Armonk, NY (US)

(21) Appl. No.: 13/087,449

(22) Filed: Apr. 15, 2011

(51) Int. Cl. H01L 23/498; G06F 11/22; H01L 21/60

(52) U.S. Cl. 257/737; 438/613; 716/112; 257/E23.068; 257/E21.508

(57) ABSTRACT

Disclosed is reinforced via farm interconnect structure for an integrated circuit chip that minimizes delamination caused by tensile stresses applied to the chip through lead-free C4 connections during thermal cycling. The reinforced via farm interconnect structure includes a plurality of vias electrically connecting metal wires within different wiring levels and, for reinforcement, further incorporates dielectric columns into the lower metal wire so that the areas around the metal-to-metal interface between the vias and the lower metal wire contain a relatively strong dielectric-to-dielectric interface. The reinforced via farm interconnect structure can be located in an area of the chip at risk for delamination and, for added strength, can have a reduced via density relative to conventional via farm interconnect structures located elsewhere on the chip. Also disclosed are a method of forming the reinforced via farm interconnect structure and a method of redesigning an integrated circuit chip to include reinforced via farm interconnect structure(s).

### BACKGROUND

1. Field of the Invention

The embodiments relate to integrated circuit chips and, more specifically, to a reinforced back end of the line (BEOL) via farm interconnect structure, a method of forming such a reinforced BEOL via farm interconnect structure and a method of redesigning an integrated circuit chip to include such a reinforced BEOL via farm interconnect structure.

2. Description of the Related Art

A flip-chip assembly (i.e., a flip-chip package) is an integrated circuit device (e.g., a semiconductor chip, a die, etc.) mounted on an organic laminate substrate (i.e., a chip carrier) by controlled collapsed chip connection (i.e., C4) attachment. Typically, such assemblies are formed by forming solder bumps on an array of conductive pads on the active surface of the integrated circuit device. The device is then “flipped” and positioned such that the device solder bumps are located adjacent to corresponding solder pads within solder resist openings on an organic laminate substrate. Solder paste within the solder resist openings on the substrate temporarily secures the solder bumps in place. Then, a reflow process is performed to create solder joints that both electrically and mechanically connect the integrated circuit device to the substrate.

Conventionally, eutectic leaded solder (Pb-63% Sn) has been used to form the solder joints in flip-chip assemblies. Recently, however, lead-free solders have been used. Unfortunately, such lead-free solders are more robust than leaded solders and, during the reflow process, may cause stress that results in delamination of the various chip layers. Therefore, there is a need in the art for an integrated circuit chip having added strength within the BEOL metal levels to avoid delamination as a result of tensile stresses applied to the chip through lead-free C4 connections, during thermal cycling associated with flip-chip package assembly.

### SUMMARY

In view of the foregoing disclosed herein are embodiments of a back end of the line (BEOL) via farm interconnect structure on an integrated circuit chip. The BEOL via farm interconnect structure is reinforced to reduce the risk of delamination as a result of tensile stresses applied to the chip through lead-free C4 connections during thermal cycling (e.g., thermal cycling associated with flip-chip package assembly) and, thereby to reduce the risk of failure. Like conventional BEOL via farm interconnect structures, each reinforced BEOL via farm interconnect structure includes a plurality of vias electrically connecting metal wires within different wiring levels. However, reinforcement is added by incorporating dielectric columns into the lower metal wire so that the areas around the metal-to-metal interface between the vias and the lower metal wire contain a relatively strong dielectric-to-dielectric interface as opposed to a relatively weak dielectric-to-metal interface. The reinforced BEOL via farm interconnect structure can be located in an area of the integrated circuit chip at risk for delamination. Optionally, the reinforced BEOL via farm interconnect structure can have a reduced via density as compared to conventional BEOL via farm interconnect structures located in other areas of the chip in order to further reduce the risk of delamination. Also disclosed herein are embodiments of a method of forming the reinforced BEOL via farm interconnect structure on an integrated circuit chip and a method of redesigning an integrated circuit chip to include such reinforced BEOL via farm interconnect structure(s).

More particularly, disclosed herein are embodiments of a reinforced BEOL via farm interconnect structure on an integrated circuit chip. The reinforced BEOL via farm interconnect structure can comprise a first trench in an upper portion of a first dielectric layer and a first metal layer within the first trench, thereby forming a first metal wire. The reinforced BEOL via farm interconnect structure can further comprise at least one second dielectric layer above the first trench, a second trench in an upper portion of the second dielectric layer and a plurality of contact openings extending vertically from the second trench through a lower portion of the second dielectric layer to a section of the first metal layer. A second metal layer can be within the second trench and within the contact openings, thereby forming a second metal wire and vias (i.e., metal-filled contact openings) that electrically connect the first and second metal wires.

Additionally, to provide reinforcement (i.e., to strengthen the BEOL via farm interconnect structure by incorporating additional features), portions of the first dielectric layer can extend vertically, as dielectric columns, through the first metal layer. These dielectric columns can be located in the same section of the first metal layer which is contacted by the vias. It should be noted that, during processing, patterning of dielectric columns in the first trench in the first dielectric layer and patterning of the contact openings in the lower portion of the second dielectric layer should be performed so that, in the resulting structure, the columns and contact openings are completely offset (i.e., so that the contacts openings do not land on the dielectric columns). The dielectric columns incorporated into the first metal layer effectively reinforce the areas around the metal-to-metal interface between the vias and the first metal wire with a relatively strong dielectric-to-dielectric interface as opposed to the relatively weak dielectric-to-metal interface seen in the prior art. Such a reinforced BEOL via farm interconnect structure can be located in an area of the integrated circuit chip determined to be at risk for delamination. For added strength (i.e., to further reduce the risk of delamination), such a reinforced BEOL via farm interconnect structure can have a reduced via density as compared to conventional BEOL via farm interconnect structures located in other areas of the chip.

Also disclosed herein are embodiments of a method of forming a reinforced BEOL via farm interconnect structure, as described above, on an integrated circuit chip. Specifically, this method can comprise forming a first trench in a first dielectric layer and further forming a first metal layer in the first trench (i.e., a first metal wire) such that the first dielectric layer has portions that extend vertically, as dielectric columns, through a section of the first metal layer. At least one second dielectric layer can then be formed above the first metal layer and the dielectric columns in the first trench. Next, the method can comprise forming a second trench in an upper portion of the second dielectric layer and a plurality of contact openings extending vertically from the second trench through a lower portion of the second dielectric layer to the section of first metal layer containing the dielectric columns. This process should be performed such that the contact openings are offset from (i.e., do not land on) the dielectric columns in the metal layer below. Once the second trench and contact openings are formed, a second metal layer can be formed in the second trench and in the plurality of contact openings, thereby forming a second metal wire and vias (i.e., metal-filled contact openings) that electrically connect the first and second metal wires.

Also disclosed herein are embodiments of a method of redesigning an integrated circuit chip to include one or more BEOL via farm interconnect structures, as described above. Specifically, this method can comprise receiving a design for an integrated circuit chip having BEOL via farm interconnect structures. Each of these BEOL via farm interconnect structures can comprise a first trench in a first dielectric layer, a first metal layer within the first trench (i.e., a first metal wire) and at least one second dielectric layer above the first metal layer. Each of these BEOL via farm interconnect structures can further comprise a second trench in an upper portion of the second dielectric layer, a plurality of contact openings extending vertically from the second trench through a lower portion of the second dielectric layer to a section of the first metal layer and a second metal layer within the second trench and within the contact openings, thereby forming a second metal wire and vias (i.e., the metal-filled contact openings) that electrically connect the first and second metal wires.

This design can then be analyzed in order to identify at least one BEOL via farm interconnect structure that is at risk of failure as a result of delamination caused by tensile stresses applied to the chip through lead-free C4 connections during thermal cycling (e.g., thermal cycling associated with flip-chip package assembly). Identification of at risk BEOL via interconnect structures can be made according to predefined rules, based on the locations of the structures on the chip. Once at risk BEOL via farm interconnect structure(s) are identified, the design of the chip and, particularly, the at risk BEOL via farm interconnect structure(s) can be altered to provide reinforcement (i.e., to strengthen the BEOL via farm interconnect structure by incorporating additional features). Specifically, the design can be altered so that, in each identified at risk BEOL via interconnect structure, the first dielectric layer has portions that extend vertically, as dielectric columns, through the section of the first metal layer contacted by the vias and so that the contact openings are offset from the columns. The dielectric columns incorporated into the first metal layer effectively reinforce the areas around the metal-to-metal interface between the vias and the first metal wire with a relatively strong dielectric-to-dielectric interface as opposed to the relatively weak dielectric-to-metal interface seen in the prior art. For added strength (i.e., to further reduce the risk of delamination), the design can further be altered such that the reinforced BEOL via farm interconnect structure(s) have a reduced via density as compared to conventional BEOL via farm interconnect structures located in other areas of the chip (e.g., by eliminating redundant vias from the reinforced BEOL via farm interconnect structures).

### BRIEF DESCRIPTION OF THE SEVERAL VIEWS OF THE DRAWINGS

The embodiments disclosed herein will be better understood from the following detailed description with reference to the drawings, which are not necessarily drawn to scale and in which:

FIG. 1 is a vertical cross-section diagram illustrating an exemplary integrated circuit chip having a via farm interconnect structure;

FIG. 2 is a horizontal cross-section diagram illustrating the same exemplary integrated circuit chip having a via farm interconnect structure as shown in FIG. 1;

FIG. 3 is a vertical cross-section diagram illustrating an embodiment of an integrated circuit chip having a reinforced via farm interconnect structure;

FIG. 4 is a horizontal cross-section diagram illustrating the same integrated circuit chip having a reinforced via farm interconnect structure as shown in FIG. 3;

FIG. 5 is a vertical cross-section diagram illustrating an alternative embodiment of an integrated circuit chip having a reinforced via farm interconnect structure;

FIG. 6 is a vertical cross-section diagram illustrating another alternative embodiment of an integrated circuit chip having a reinforced via farm interconnect structure;

FIG. 7 is a vertical cross-section diagram illustrating yet another alternative embodiment of an integrated circuit chip having a reinforced via farm interconnect structure;

FIG. 8 is a horizontal cross-section diagram illustrating yet another alternative embodiment of an integrated circuit chip having a reinforced via farm interconnect structure;

FIG. 9 is a flow diagram illustrating an embodiment of a method of forming an integrated circuit chip having a reinforced via farm interconnect structure;

FIG. 10A is a vertical cross-section diagram illustrating a partially completed integrated circuit structure formed according to the method of FIG. 9;

FIG. 10B is a horizontal cross-section diagram illustrating the same partially completed integrated circuit structure as shown in FIG. 10B;

FIG. 11A is a vertical cross-section diagram illustrating a partially completed integrated circuit structure formed according to the method of FIG. 9;

FIG. 11B is a horizontal cross-section diagram illustrating the same partially completed integrated circuit structure as shown in FIG. 10B;

FIG. 12 is a vertical cross-section diagram illustrating a partially completed integrated circuit structure formed according to the method of FIG. 9;

FIG. 13 is a vertical cross-section diagram illustrating a partially completed integrated circuit structure formed according to the method of FIG. 9;

FIG. 14 is a flow diagram illustrating an embodiment of a method of redesigning an integrated circuit chip to include a reinforced via farm interconnect structure; and

FIG. 15 is a schematic diagram illustrating an exemplary hardware environment that can be used to implement the method embodiment of FIG. 14.

### DETAILED DESCRIPTION

The embodiments and the various features and advantageous details thereof are explained more fully in the detailed description below with reference to the accompanying drawings.

A flip-chip assembly (i.e., a flip-chip package) is an integrated circuit device (e.g., a semiconductor chip, a die, etc.) mounted on an organic laminate substrate (i.e., a chip carrier) by controlled collapsed chip connection (i.e., C4) attachment. Typically, such assemblies are formed by forming solder bumps on an array of conductive pads on the active surface of the integrated circuit device. The device is then “flipped” and positioned such that the device solder bumps are located adjacent to corresponding solder pads within solder resist openings on an organic laminate substrate. Solder paste within the solder resist openings on the substrate temporarily secures the solder bumps in place. Then, a reflow process is performed to create solder joints that both electrically and mechanically connect the integrated circuit device to the substrate. Conventionally, eutectic leaded solder (Pb-63% Sn) has been used to form the solder joints in flip-chip assemblies. Such leaded solder has the advantage of mitigating coefficient of thermal expansion (CTE) mismatch between the chip and the substrate (i.e., organic laminate) and, thereby preventing wiring layers within the chip from delaminating or other damage from occurring to the chip or the substrate.

Recently, however, government regulations around the world have required lead (Pb)-free electronics components. Thus, lead-free C4 connections incorporating tin (Sn)-based solders (e.g., Sn-copper (Cu) solder, Sn-silver (Ag) solder or Sn—Ag—Cu (also SAC) solder) have been developed to replace leaded C4 connections. Unfortunately, the lower ductility Sn-based solders, having a Young's modulus of 50 gigapascals (GPa), as compared to Pb-based solders, having a Young's modulus of 16 GPa, results in CTE mismatch between the chip and substrate during the assembly process and, particularly, during the cooling cycle following solder reflow. This CTE mismatch can cause a transfer of stress through the C4 connections and in turn can cause cracks in chip metallurgy under the C4 connections. Such cracks have been referred to as “white bumps” due to their appearance in acoustic imaging type inspection processes.

More specifically, in practice, the organic laminate substrate (i.e., the chip carrier) typically has a CTE of about 18 to 20; whereas, an integrated circuit chip typically has a CTE of about 2. During the soldering process, e.g., reflow oven, the temperatures can range from about 250° C. to 260° C. This high temperature expands the organic laminate substrate more than it does the chip due to the CTE differences. As the resulting package (i.e., the organic laminate substrate and chip electrically and mechanically connected by lead-free C4 connections) begins to cool, the lead-free solder begins to solidify (e.g., at about 180° C.), the organic laminate substrate begins to shrink, but the chip remains substantially the same size. Since the lead-free solder is robust and exceeds the strength of the chip, the tensile stresses applied to the chip through the lead-free C4 connections can exceed the yield strength of chip causing delamination of various layers within the chip and, particularly, within the back end of the line (BEOL) of the chip.

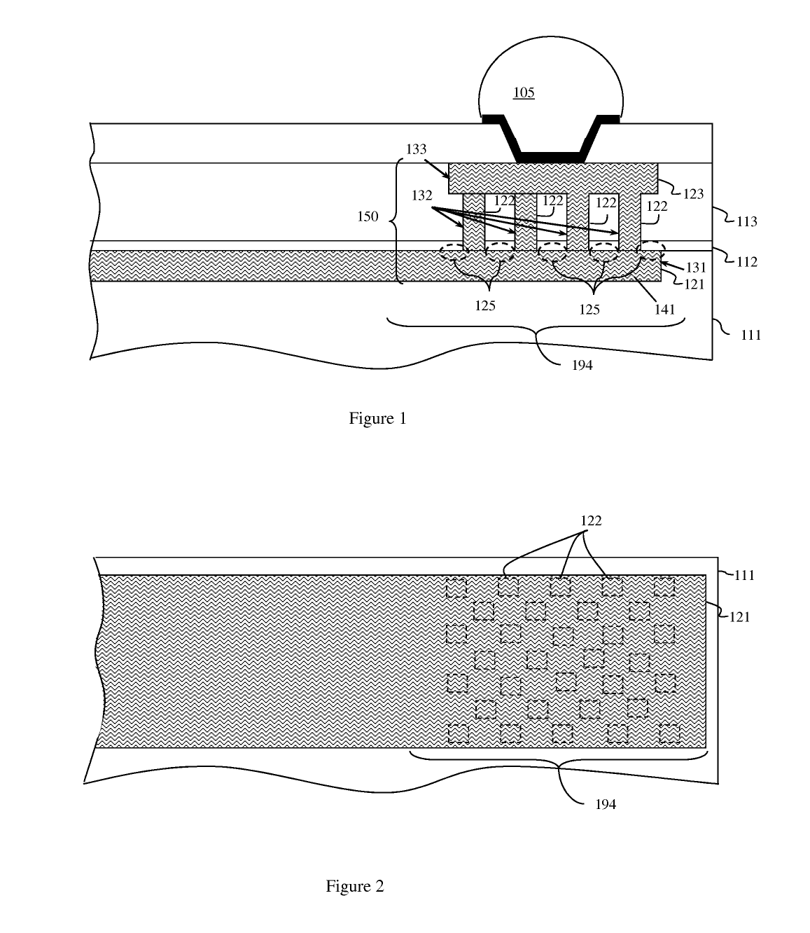

Delamination can be particularly notable within via farm interconnect structures in the back end of the line (BEOL) wiring levels of the chip. For example, FIG. 1 illustrates an exemplary integrated circuit chip having a via farm interconnect structure 150 comprising a metal wire 123 (e.g., a copper pad) electrically connected to another metal wire 121 (e.g., a copper layer) by a plurality of vias 122 (i.e., a plurality of metal-filled contact openings). Specifically, the metal wire 123 can be positioned within an upper portion of a dielectric layer (e.g., in an upper portion of a silicon dioxide (SiO₂) layer 113) of a BEOL wiring level (e.g., the highest or last BEOL wiring level). The metal wire 121 can be positioned within an upper portion of another dielectric layer (e.g., in the upper portion of another silicon dioxide (SiO₂) layer 111) in a lower BEOL wiring level (e.g., the last minus one BEOL wiring level). The vias 122 can extend vertically from the metal wire 123 through a lower portion of the silicon dioxide (SiO₂) layer 13 and through a silicon nitride (SiN) layer 112 to the section 194 of metal wire 121 aligned below. FIG. 2 is a horizontal cross-section illustration of this same integrated circuit chip 100 through the interface between the metal wire 121 and the SiN layer 112, showing exemplary locations on the metal wire 121 contacted by the vias 122.

Unfortunately, when lead-free C4 connections 105 are used to electrically and mechanically connect the chip 1 to the organic laminate substrate (i.e., the chip carrier) this via farm interconnect structure 150 may be at risk for failure during thermal cycling due to the relatively low strength of the attachment between the metal wire 121 and the SiN layer 112, particular in the areas 125 surrounding the vias 122. That is, the attachment between the lower metal wire 121 and the SiN layer 112 is relatively weak and can crack during thermal cycling due the tensile stresses applied to the chip 100 through the lead-free C4 connections. Such a crack can in turn spread, causing one or more of the vias 122 to become disconnected from the metal wire 21. Since the amount of tensile stress applied to the via farm interconnect structure 150 varies depending upon the structure's location on the chip 100 and its location relative to any C4 connections 105, so will the risk of failure.

For example, a via farm interconnect structure 150 will be subject to greater tensile stress during thermal cycling and, therefore, at greater risk of failure when it is located on the outer edge of the chip particularly either when it is in the two highest wiring levels directly connected to solder ball 105 (as shown in FIG. 1) or, to a lesser extent, when it is in any two lower wiring levels. A via farm interconnect structure 150 will also be subject to greater tensile stress during thermal cycling and, therefore, at greater risk of failure when it is located in the highest two wiring levels and further offset from a C4 connection (i.e., not center aligned with a C4 connection). Finally, a via farm interconnect structure 150 will be subject to greater tensile stress during thermal cycling and, therefore, at greater risk of failure when it is located along the chip diagonal either when it is in the highest two wiring levels or, to a lesser extent, when it is in any lower two wiring levels.

In view of the foregoing disclosed herein are embodiments of a back end of the line (BEOL) via farm interconnect structure on an integrated circuit chip. The BEOL via farm interconnect structure is reinforced to reduce the risk of delamination as a result of tensile stresses applied to the chip through lead-free C4 connections during thermal cycling (e.g., thermal cycling associated with flip-chip package assembly) and, thereby to reduce the risk of failure. Like conventional BEOL via farm interconnect structures, the reinforced BEOL via farm interconnect structure includes a plurality of vias electrically connecting metal wires within different wiring levels. However, reinforcement is added by incorporating dielectric columns into the lower metal wire so that the areas around the metal-to-metal interface between the vias and the lower metal wire contain a relatively strong dielectric-to-dielectric interface as opposed to a relatively weak dielectric-to-metal interface. The reinforced BEOL via farm interconnect structure can be located in an area of the integrated circuit chip at risk for delamination. Optionally, the reinforced BEOL via farm interconnect structure can have a reduced via density as compared to conventional BEOL via farm interconnect structures located in other areas of the chip in order to further reduce the risk of delamination. Also disclosed herein are embodiments of a method of forming a reinforced BEOL via farm interconnect structure on an integrated circuit chip and a method of redesigning an integrated circuit chip to include such reinforced BEOL via farm interconnect structure(s).

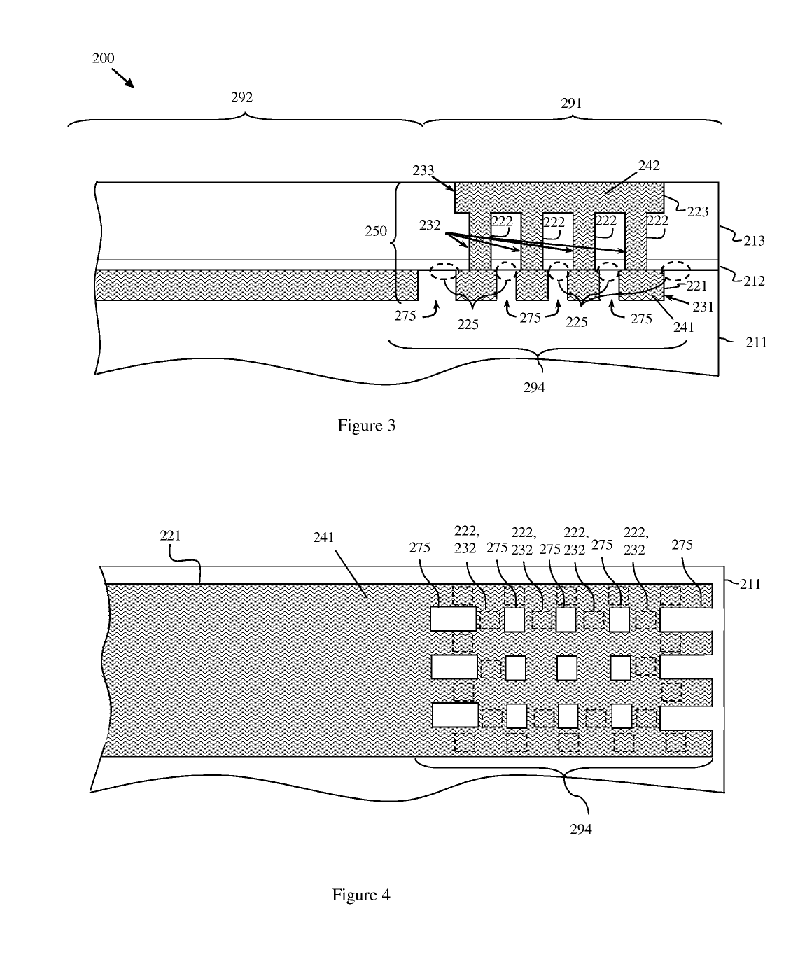

More particularly, referring to FIG. 3, disclosed herein are embodiments of a reinforced BEOL via farm interconnect structure 250 on an integrated circuit chip 200. The reinforced BEOL via farm interconnect structure 250 can comprise a first dielectric layer 211. This first dielectric layer 211 can comprise, for example, a silicon dioxide (SiO2) layer or any other dielectric material suitable for use within BEOL wiring levels. A first trench 231 can be in an upper portion of the first dielectric layer 211. The first trench 231 can, optionally, be lined with a conductive barrier layer (e.g., titanium nitride (TiN), tantalum nitride (TaN), tantalum (Ta) or any other conductive barrier material suitable for preventing diffusion of contact conductor material into the adjacent dielectric layer 211). A first metal layer 241 can further be within the first trench 231 (on the liner, if applicable), thereby forming a first metal wire 221. This first metal layer 241 can, for example, comprise a copper (Cu) layer, an aluminum (Al) layer or any other metal or metal alloy layer or stack of layers suitable for use as in a BEOL via farm interconnect structure).

Each reinforced BEOL via farm interconnect structure 250 can further comprise at least one second dielectric layer above the first trench 231. The second dielectric layer(s) can comprise any dielectric material suitable for use within EOL wiring levels. For example, a silicon nitride (SiN) layer 212 can cover the first trench 231 and a silicon dioxide (SiO2) layer 213 can be stacked on top of the SiN layer 212. A second trench 233 can be in an upper portion of the second dielectric layer (or stack of second dielectric layers 212-213, as applicable) and a plurality of contact openings 232 can extend vertically from the second trench 233 through a lower portion of the second dielectric layer (or stack of second dielectric layers 212-213, as applicable) to a section 294 of the first metal layer 241 below. The second trench 233 and contact openings 232 can, optionally, be lined with a conductive barrier layer (e.g., titanium nitride (TiN), tantalum nitride (TaN), tantalum (Ta) or any other conductive barrier material suitable for preventing diffusion of contact conductor material into the adjacent dielectric layer(s) 212-213). A second metal layer 242 can be within the second trench 233 and within the contact openings 232, thereby forming a second metal wire 223 and vias 222 (i.e., metal-filled contact openings) that electrically connect the first and second metal wires 221, 223 Like the first metal layer 241, the second metal layer 242 can, for example, comprise a copper (Cu) layer, an aluminum (Al) layer or any other metal or metal alloy layer or stack of layers suitable for use in a via farm interconnect structure).

Additionally, to provide reinforcement (i.e., to strengthen the BEOL via farm interconnect structure by incorporating additional features), portions of the first dielectric layer can extend vertically, as dielectric columns 275, through the first metal layer 241. These dielectric columns 275 can be located in the same section 294 of the first metal layer 241 which is contacted by the vias 222. It should be noted that, during processing, patterning of dielectric columns 275 in the first trench 231 in the first dielectric layer 211and patterning of the contact openings 232 in the lower portion of the second dielectric layer (or stack of second dielectric layers 212-213, as applicable) should be performed so that, in the resulting structure, the dielectric columns 275 and contact openings 232 are completely offset (i.e., so that the contacts openings 232 do not land on the dielectric columns 275). FIG. 4 is a horizontal cross-section diagram of the reinforced BEOL via farm interconnect structure 250 of FIG. 3 at the interface between the metal wire 221 and the second dielectric layer(s) 212-213 illustrating exemplary positioning of the dielectric columns 275 relative to locations where the vias 222 land on the section 294 of the first metal layer 241. As illustrated, there is no overlap. It should be noted that the shape of both the dielectric columns 275 and the contact openings 232 is shown, for illustration purposes, in the cross-section of FIG. 4 as being a rectangle. However, it should be understood that this shape could, alternatively, be a square, a circle, an oval, etc.

Referring again to FIG. 3, the dielectric columns 275 that are incorporated into the section 294 of the first metal layer 241 effectively reinforce the areas 225 around the metal-to-metal interface between the vias 222 and the first metal wire 221 with a relatively strong dielectric-to-dielectric interface as opposed to the relatively weak dielectric-to-metal interface seen in the prior art. Thus, such a reinforced BEOL via farm interconnect structure 250, having a section 294 of a first metal layer 241 containing dielectric columns 275, can be located in an area of the integrated circuit chip 200 determined to be at risk for delamination particularly during thermal cycling associated with the flip-chip assembly process.

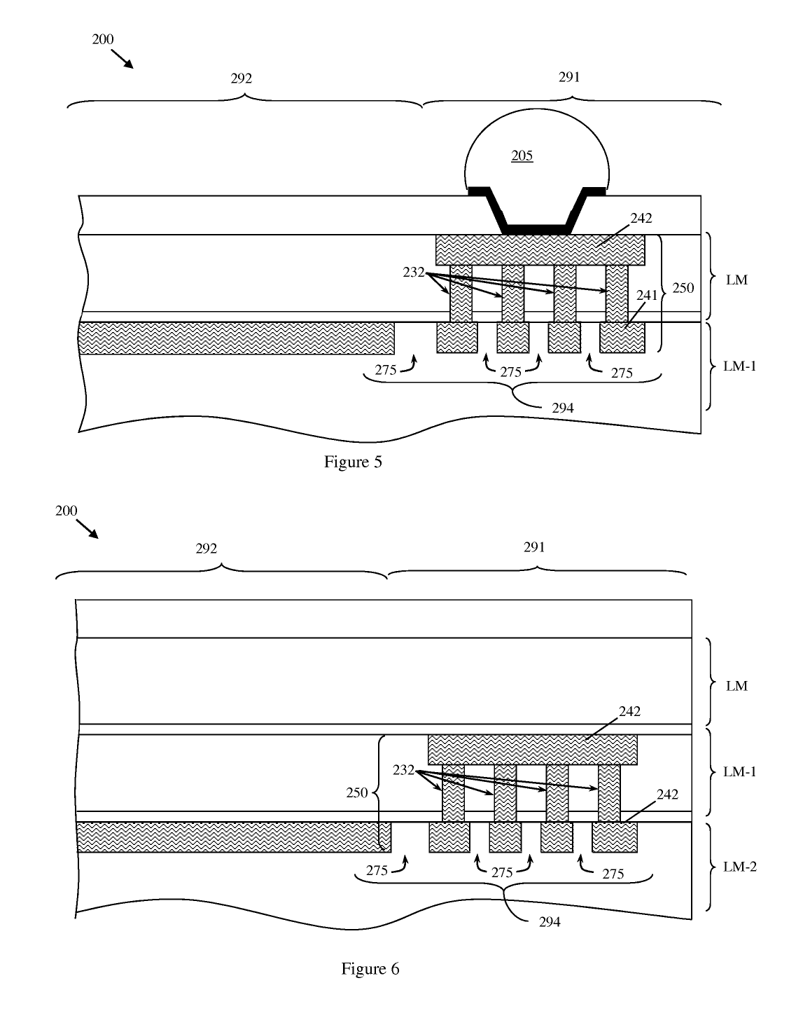

For example, as mentioned above, a via farm interconnect structure will be subject to greater tensile stress during thermal cycling and, therefore, at greater risk of failure when it is located on the outer edge of the chip either when it is in the two highest wiring levels directly connected to solder ball or, to a lesser extent, when it is in any two lower wiring levels. Thus, as illustrated in FIG. 3, a reinforced BEOL via farm interconnect structure 250, having a section 294 of a first metal layer 241 containing dielectric columns 275, can be located within an outer edge portion 291 of the integrated circuit chip 200 as opposed to a center portion 292 of the chip 200. More specifically, as illustrated in FIG. 5, such a reinforced BEOL via farm interconnect structure 250 can be located within an outer edge portion 291 of the chip 200 in the two highest wiring levels (i.e., last metal level (LM) and last metal level minus one (LM−1)). In this case, a lead-free solder bump 205 can be positioned on the second metal layer 242 (e.g., aligned above the contact openings 232 and dielectric columns 275). Additionally or alternatively, as illustrated in FIG. 6, such a reinforced BEOL via farm interconnect structure 250 can be located within an outer edge portion 291 of the chip 200 in two lower wiring levels (e.g., the last metal level minus one (LM−1) and the last metal level minus two (LM−2)) such that no solder bumps are positioned on the second metal layer 242.

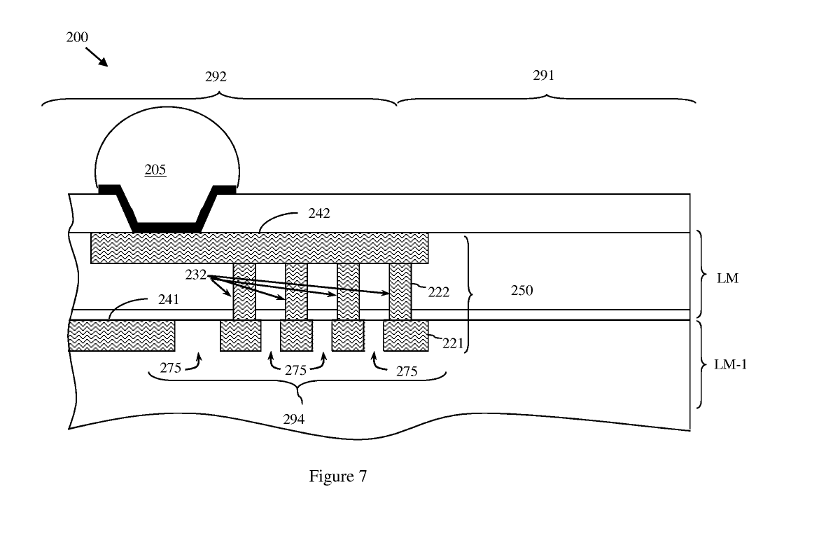

Also as mentioned above, a via farm interconnect structure will be subject to greater tensile stress during thermal cycling and, therefore, at greater risk of failure when it is located in the highest two wiring levels and further offset from a C4 connection (i.e., not center aligned with a C4 connection). Thus, as illustrated in FIG. 7, a reinforced BEOL via farm interconnect structure 250 can be located within any portion of the chip 200 (e.g., the center portion or the outer edge portion) in the two highest wiring levels (i.e., last metal level (LM) and last metal level minus one (LM−1)) particularly when a solder bump 205 is positioned on the second metal layer 242 but offset from (i.e., not aligned above) the plurality of contact openings 232.

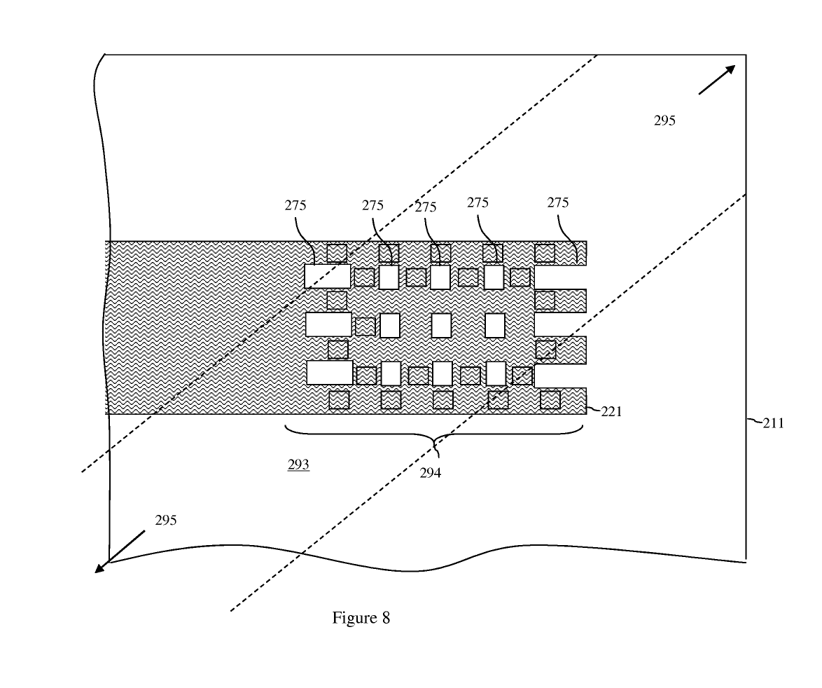

Finally, also as mentioned above, a via farm interconnect structure will be subject to greater tensile stress during thermal cycling and, therefore, at greater risk of failure when it is located along the chip diagonal either when it is in the highest two wiring levels or, to a lesser extent, when it is in any lower two wiring levels. Thus, as illustrated in FIG. 8, a reinforced BEOL via farm interconnect structure 250 can be located within a predefined area 293 of the chip 200 extending along the chip diagonal (i.e., between opposite corners 295 of the integrated circuit chip 200).

For added strength (i.e., to further reduce the risk of delamination due to thermal cycling), the reinforced BEOL via farm interconnect structure 250, as illustrated in any of the FIGS. 3-8 and described in detail above, can further have a reduced via density (e.g., reduced by 25%, reduced by 50%, etc.) as compared to the via density of any conventional BEOL via farm interconnect structures located on the chip. Specifically, the chip 200 can further comprise one or more conventional via farm interconnect structures (e.g., as illustrated in FIG. 1 and described in detail above) and, in this case, the number of vias 222 with the section 294 of each reinforced BEOL via farm interconnect structure 250 would be less than (e.g., 25% less than, 50% less than, etc.) the number of vias in each conventional BEOL via farm inter connect structure landing on the same-sized section of a lower metal layer.

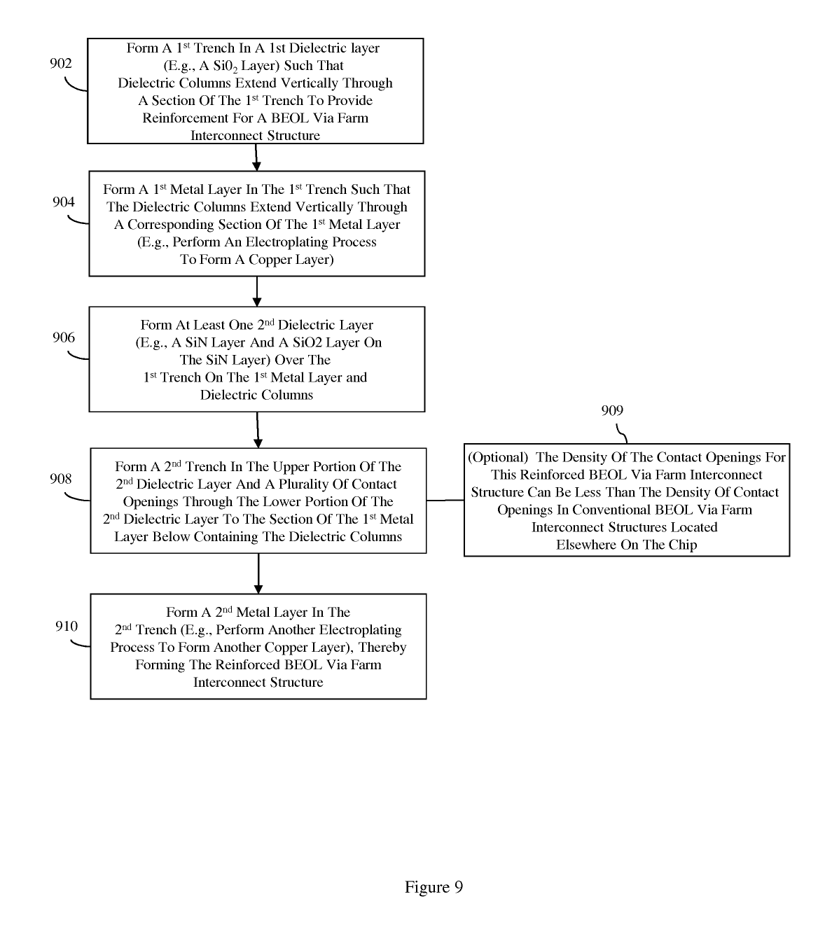

Also disclosed herein are embodiments of a method of forming a reinforced BEOL via farm interconnect structure 250, as described above and illustrated in FIGS. 3-8, on an integrated circuit chip. Specifically, this method can comprise performing front and middle of the line processing of a substrate for formation of an integrated circuit chip according to a design. Following front and middle of the line processing, performing back end of the line (BEOL) wiring level processing, including forming device to device interconnect structures as well as interconnect structures to solder bumps for controlled collapsed chip connection (i.e., C4) to an organic laminate substrate (i.e., a chip carrier). The interconnect structures formed during this BEOL processing can include via farm interconnect structures and at least one of these via farm interconnect structures can comprise a reinforced via farm interconnect structure. Such a reinforced BEOL via farm interconnect structure can be formed according to the method as set forth in the flow diagram of FIG. 9.

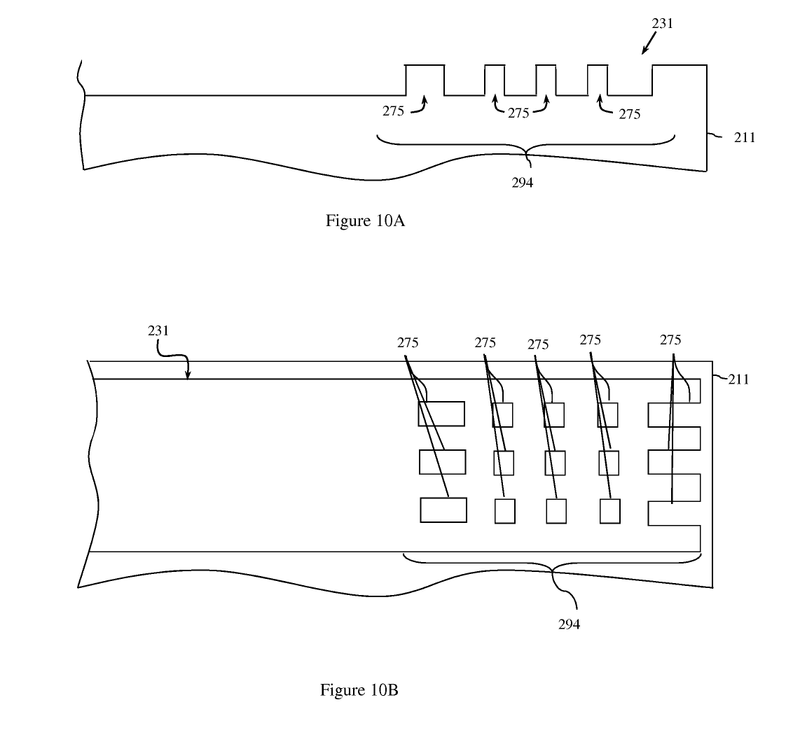

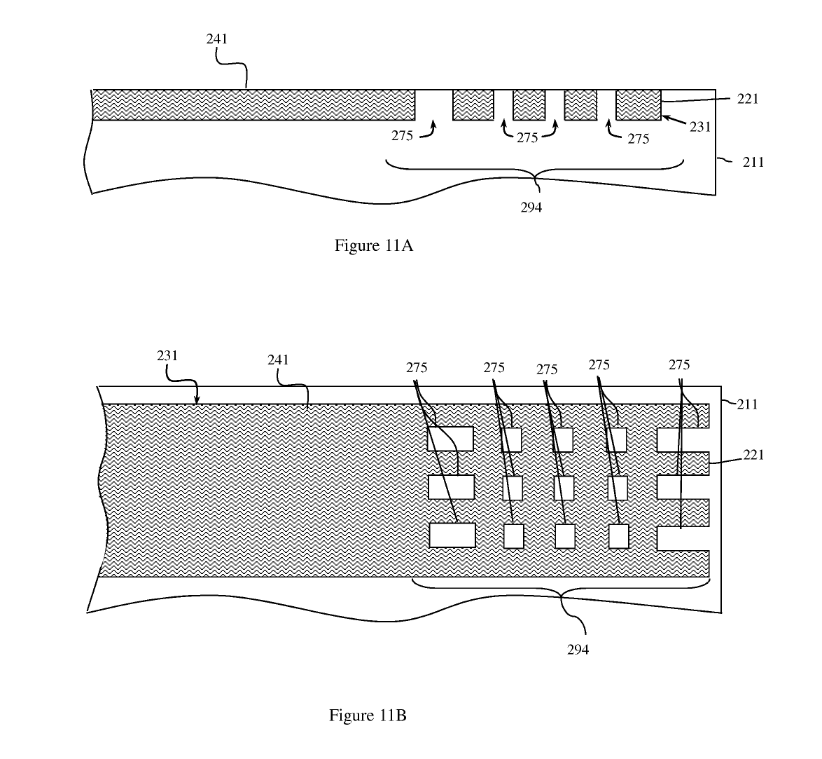

Specifically, a first trench 231 can be formed in an upper portion of a first dielectric layer 211 (e.g., a silicon dioxide (SiO2) layer or any other dielectric material suitable for use within BEOL wiring levels) (902, see FIGS. 10A-10B). This first trench 231 can specifically be formed such that portions of the first dielectric layer extend vertically through into a section 294 of the first trench 231, as dielectric columns 275, in the desired location of the via farm interconnect structure. Such a trench 231 with dielectric columns 275 can, for example, be formed using conventional lithographic patterning and etch processes. Such processes are well-known in the art and, thus, the details are omitted from this specification in order to allow the reader to focus on the salient aspects of the disclosed embodiments.

Next, the first trench 231 can, optionally, be lined with a conductive barrier layer (e.g., titanium nitride (TiN), tantalum nitride (TaN), tantalum (Ta) or any other conductive barrier material suitable for preventing diffusion of contact conductor material into the adjacent dielectric layer 211). Then, a first metal layer 241 (e.g. a copper (Cu) layer, an aluminum (Al) layer or any other metal or metal alloy layer or stack of layers suitable for use as in a BEOL via farm interconnect structure) can be formed within the first trench 231 (on the liner, if applicable), thereby forming a first metal wire 221 (904, see FIGS. 11A-11B). This first metal layer 241 can, for example, be formed using conventional electroplating processes. Such processes are well-known in the art and, thus, the details are omitted from this specification in order to allow the reader to focus on the salient aspects of the disclosed embodiments.

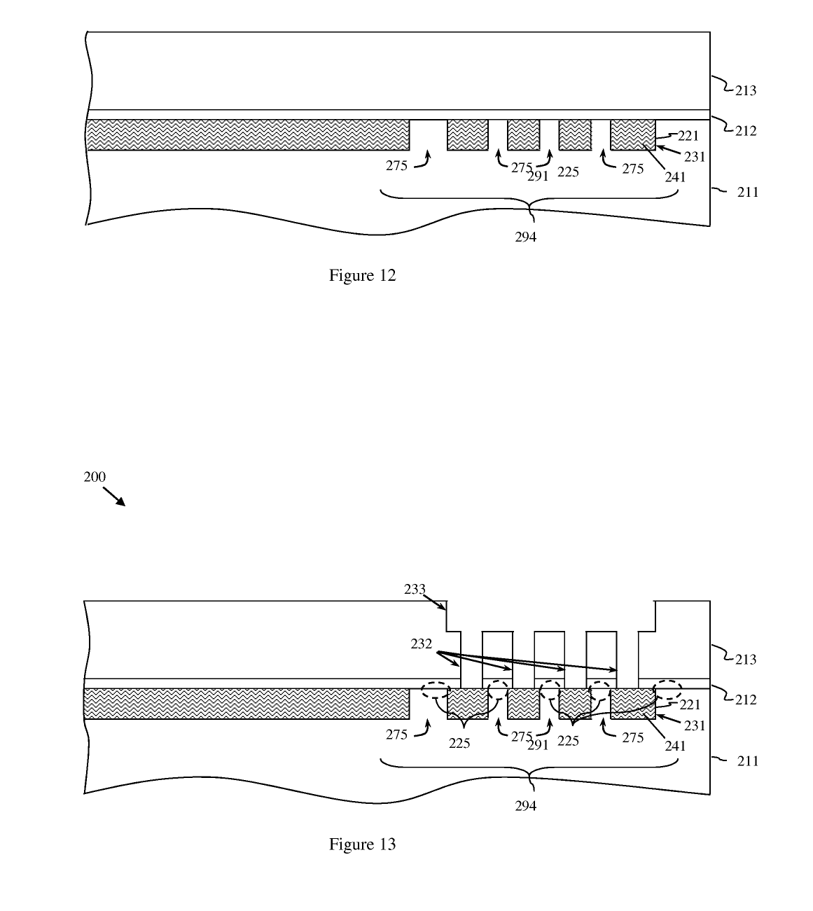

After the first metal wire 221 is formed at process 904, at least one second dielectric layer can then be formed above the first metal layer 241 and the dielectric columns 275 in the first trench 231 (906, see FIG. 12). The second dielectric layer(s) can comprise any dielectric material suitable for use within EOL wiring levels. For example, a silicon nitride (SiN) layer 212 can be formed (e.g., deposited) such that it covers the first trench 231 and a silicon dioxide (SiO2) layer 213 can be formed (e.g., deposited) such that it is stacked on top of the SiN layer 212.

Next, the method can comprise forming a second trench 233 in an upper portion of the second dielectric layer (or the upper portion of the stack of second dielectric layers 212-213, as applicable) and a plurality of contact openings 232 extending vertically from the second trench 233 through a lower portion of the second dielectric layer (or the lower portion of the stack of second dielectric layers 212-213, as applicable) to the section 294 of first metal layer 241 containing the dielectric columns 275 (908, see FIG. 13). The second trench 233 and contact openings 232 can be formed, for example, using conventional dual damascene processes. Such processes are well-known in the art and, thus, the details are omitted from this specification in order to allow the reader to focus on the salient aspects of the disclosed embodiments. During the dual damascene processing, the contact openings 232 should be lithographically patterned such that the land on the first metal layer 241 and are offset from (i.e., do not land on) the dielectric columns 275.

Once the second trench 231 and contact openings 232 are formed at process 908, the second trench 233 and contact openings 232 can, optionally, be lined with a conductive barrier layer (e.g., titanium nitride (TiN), tantalum nitride (TaN), tantalum (Ta) or any other conductive barrier material suitable for preventing diffusion of contact conductor material into the adjacent dielectric layer(s) 212-213). Then, a second metal layer 242 (e.g. a copper (Cu) layer, an aluminum (Al) layer or any other metal or metal alloy layer or stack of layers suitable for use as in a BEOL via farm interconnect structure) can be formed within the second trench 233 and within the contact openings 232, thereby forming a second metal wire 223 and vias 222 (i.e., metal-filled contact openings) that electrically connect the first and second metal wires 221, 223 (i.e., thereby forming the reinforced BEOL via farm interconnect structure 250) (910, see FIG. 3) Like the first metal layer 241, the second metal layer 242 can, for example, be formed using conventional electroplating processes. Such processes are well-known in the art and, thus, the details are omitted from this specification in order to allow the reader to focus on the salient aspects of the disclosed embodiments.

It should be noted that, optionally, for added strength, the contact openings 232 can be formed at process 908 such that the density of the contact openings 232 (i.e., the number of contacts openings landing on the section 294 of the first metal layer 241) is less (e.g., by 25%, by 50%, etc.) than the density of contact openings in conventional BEOL via farm interconnect structures formed elsewhere on the chip (i.e., the number of contacts openings landing on the same size section of a lower metal layer in non-reinforced BEOL via farm interconnect structures on the chip) (909). Thus, following process 910, the density of the vias 222 in the reinforced BEOL via farm interconnect structure 250 (as shown in FIG. 4) will necessarily be less than the density of vias in non-reinforced BEOL via farm interconnect structures on the chip (as shown in FIG. 2).

It should further be noted that, in the resulting reinforced BEOL via farm interconnect structure 250 formed by processes 902-910, the dielectric columns 275 that are incorporated into the section 294 of the first metal layer 241 will effectively reinforce the areas 225 around the metal-to-metal interface between the vias 222 and the first metal wire 221 with a relatively strong dielectric-to-dielectric interface as opposed to the relatively weak dielectric-to-metal interface seen in the prior art. Thus, the processes 902-910 described above can be performed so that the reinforced BEOL via farm interconnect structure 250, having a section 294 of a first metal layer 241 containing dielectric columns 275, is located in an area of the integrated circuit chip 200 previously determined to be at risk for delamination particularly during thermal cycling associated with the flip-chip assembly process.

For example, as mentioned above, a via farm interconnect structure will be subject to greater tensile stress during thermal cycling and, therefore, at greater risk of failure when it is located on the outer edge of the chip either when it is in the two highest wiring levels directly connected to solder ball or, to a lesser extent, when it is in any two lower wiring levels. Thus, as illustrated in FIG. 3, a reinforced BEOL via farm interconnect structure 250, having a section 294 of a first metal layer 241 containing dielectric columns 275, can be formed at process 902-910 so as to be located within an outer edge portion 291 of the integrated circuit chip 200 as opposed to a center portion 292 of the chip 200. More specifically, as illustrated in FIG. 5, such a reinforced BEOL via farm interconnect structure 250 can be formed so that it is located within an outer edge portion 291 of the chip 200 in the two highest wiring levels (i.e., last metal level (LM) and last metal level minus one (LM−1)). In this case, a lead-free solder bump 205 can be positioned on the second metal layer 242 (e.g., aligned above the contact openings 232 and dielectric columns 275). Additionally or alternatively, as illustrated in FIG. 6, a reinforced BEOL via farm interconnect structure 250 can be formed at process 902-910 so as that it is located within an outer edge portion 291 of the chip 200 in two lower wiring levels (e.g., the last metal level minus one (LM−1) and the last metal level minus two (LM−2)) such that no solder bumps are positioned on the second metal layer 242.

Also as mentioned above, a via farm interconnect structure will be subject to greater tensile stress during thermal cycling and, therefore, at greater risk of failure when it is located in the highest two wiring levels and further offset from a C4 connection (i.e., not center aligned with a C4 connection). Thus, as illustrated in FIG. 7, a reinforced BEOL via farm interconnect structure 250 can be formed at processes 902-910 so that it is located within any portion of the chip 200 (e.g., the center portion or the outer edge portion) in the two highest wiring levels (i.e., last metal level (LM) and last metal level minus one (LM−1)) particularly when a solder bump 205 is positioned on the second metal layer 242 but offset from (i.e., not aligned above) the plurality of contact openings 232.

Finally, also as mentioned above, a via farm interconnect structure will be subject to greater tensile stress during thermal cycling and, therefore, at greater risk of failure when it is located along the chip diagonal either when it is in the highest two wiring levels or, to a lesser extent, when it is in any lower two wiring levels. Thus, as illustrated in FIG. 8, a reinforced BEOL via farm interconnect structure 250 can be formed at process 902-910 so that it is located within a predefined area 293 of the chip 200 extending along the chip diagonal (i.e., between opposite corners 295 of the integrated circuit chip 200).

It should be understood that this method as described above and illustrated in FIG. 9 is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

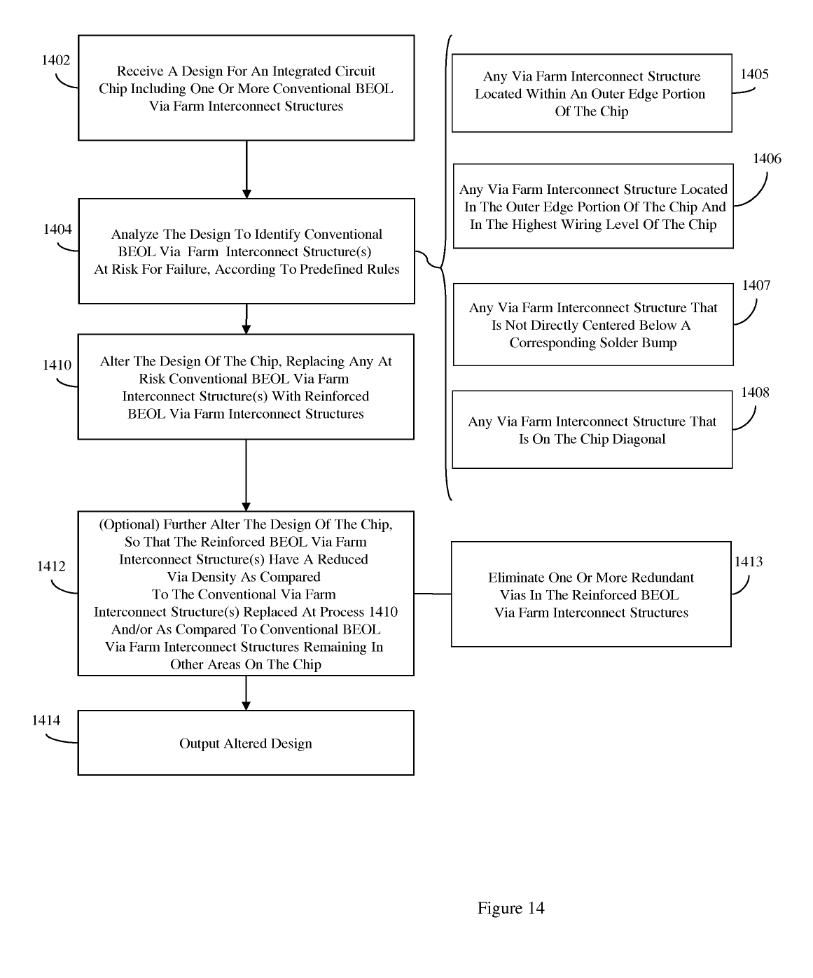

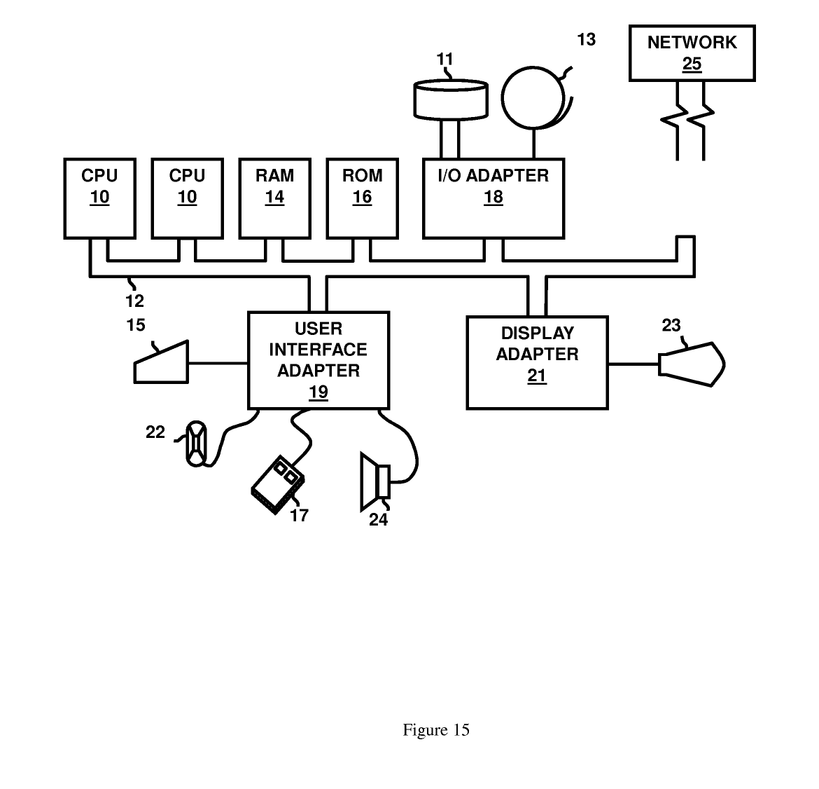

Referring to FIG. 14, also disclosed herein are embodiments of a computer-implemented method of redesigning an integrated circuit chip to include one or more BEOL via farm interconnect structures (1402). Specifically, this method can comprise receiving (e.g., by a computer system such as the system described below and illustrated in FIG. 15) a design for an integrated circuit chip having BEOL via farm interconnect structures, such as the BEOL via farm structure 150 described above and illustrated in FIG. 1 (1402). That is, as shown in FIG. 1, each of these BEOL via farm interconnect structures 150 can comprise a first trench 131 in a first dielectric layer 111, a first metal layer 141 within the first trench 131 (i.e., a first metal wire 121) and at least one second dielectric layer 112-113 above the first metal layer 141. Each of these BEOL via farm interconnect structures 150 can further comprise a second trench 133 in an upper portion of the second dielectric layer(s) 112-113, a plurality of contact openings 132 extending vertically from the second trench 133 through a lower portion of the second dielectric layer(s) 112-113 to a section 194 of the first metal layer 141 and a second metal layer 142 within the second trench 133 and within the contact openings 132, thereby forming a second metal wire 123 and vias 122 (i.e., the metal-filled contact openings) that electrically connect the first and second metal wires 121, 123.

This design can then be analyzed (e.g., by a processor 10 in the computer system described below and illustrated in FIG. 15) in order to identify at least one BEOL via farm interconnect structure that is at risk of failure as a result of delamination caused by tensile stresses applied to the chip through lead-free C4 connections during thermal cycling (e.g., thermal cycling associated with flip-chip package assembly) (1404). Identification of at risk BEOL via interconnect structures can be made according to predefined rules, based on the locations of the structures on the chip. For example, the predefined rules can specify at least one of the following: (1) any via farm interconnect structure in the design that is located within an outer edge portion of the integrated circuit chip is at risk of failure (1405); (2) any via farm interconnect structure in the design that is located within an outer edge portion of the integrated circuit chip and in the highest wiring level of the integrated circuit chip is at risk (1406); (3) any via farm interconnect structure in the design that is not directly centered below a corresponding solder bump is at risk of failure (1407); and/or (4) any via farm interconnect structure in the design that is located on the chip diagonal within a predefined area extending between opposite corners of the integrated circuit chip is at risk of failure (1408).

Once at risk BEOL via farm interconnect structure(s) are identified, the design of the chip and, particularly, the at risk BEOL via farm interconnect structure(s) can be altered (e.g., by a processor 10 in the computer system described below and illustrated in FIG. 15) to provide reinforcement (i.e., to strengthen the BEOL via farm interconnect structure by incorporating additional features) (1410). Specifically, the design can be altered so that, each identified at risk BEOL via interconnect structure, is replaced with a reinforced BEOL via farm interconnect structure 250, as described in detail above and illustrated in FIGS. 3-8. For added strength (i.e., to further reduce the risk of delamination), the design can further be altered such that the reinforced BEOL via farm interconnect structure(s) have a reduced via density as compared to conventional BEOL via farm interconnect structures replaced at process 1410 and/or as compared to conventional BEOL via farm interconnect structures remaining in other areas of the chip. The via density can be reduced, for example, by 25%, by 50%, etc. This can be accomplished, for example, by eliminating redundant vias from the reinforced BEOL via farm interconnect structures (1413). This altered design can then be output and released to, for example, to tape-out, manufacturing, a mask house, is sent to another design process, etc. (1414).

As will be appreciated by one skilled in the art, aspects of the disclosed embodiments and, particularly, aspects of the method of redesigning an integrated circuit, as set out in FIG. 14 and described in detail above, may be implemented, for example, using a computer system or a computer system that executes a computer program product. Accordingly, aspects of the disclosed embodiments may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present disclosed embodiments may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the disclosed embodiments may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the disclosed embodiments are described above with reference to flowchart illustrations and/or block diagrams of methods, apparatus (systems) and computer program products according to disclosed embodiments. It will be understood that each block of the flowchart illustrations and/or D-2 block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

A representative hardware environment for practicing the disclosed embodiments and, particularly, the method of redesigning an integrated circuit, as set forth in FIG. 14 and described in detail above, is depicted in FIG. 15. This schematic drawing illustrates a hardware configuration of an information handling/computer system in accordance with the disclosed embodiments. The system comprises at least one processor or central processing unit (CPU) 10. The CPUs 10 are interconnected via system bus 12 to various devices such as a random access memory (RAM) 14, read-only memory (ROM) 16, and an input/output (I/O) adapter 18. The I/O adapter 18 can connect to peripheral devices, such as disk units 11 and tape drives 13, or other program storage devices that are readable by the system. The system can read the inventive instructions on the program storage devices and follow these instructions to execute the methodology of the disclosed embodiments. The system further includes a user interface adapter 19 that connects a keyboard 15, mouse 17, speaker 24, microphone 22, and/or other user interface devices such as a touch screen device (not shown) to the bus 12 to gather user input. Additionally, a communication adapter 20 connects the bus 12 to a data processing network 25, and a display adapter 21 connects the bus 12 to a display device 23 which may be embodied as an output device such as a monitor, printer, or transmitter, for example.

The flowchart and block diagrams in the Figures illustrate the architecture, functionality, and operation of possible implementations of systems, methods and computer program products according to various disclosed embodiments. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

It should be understood that the flowchart and block diagrams in the Figures illustrate the architecture, functionality, and operation of possible implementations of systems, methods and computer program products according to the various disclosed embodiments. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

It should further be understood that the terminology used herein is for the purpose of describing particular embodiments only and is not intended to be limiting of the disclosed embodiments. As used herein, the singular forms “a”, “an” and “the” are intended to include the plural forms as well, unless the context clearly indicates otherwise. It should further be understood that the terms “comprises” “comprising”, “includes” and/or “including”, as used in this specification, specify the presence of stated features, integers, steps, operations, elements, and/or components, but do not preclude the presence or addition of one or more other features, integers, steps, operations, elements, components, and/or groups thereof. Additionally, it should be understood that the corresponding structures, materials, acts, and equivalents of all means or step plus function elements in the claims below are intended to include any structure, material, or act for performing the function in combination with other claimed elements as specifically claimed. The description of the disclosed embodiments has been presented for purposes of illustration and description, but is not intended to be exhaustive or limited to the embodiments in the forms disclosed. Many modifications and variations will be apparent to those of ordinary skill in the art without departing from the scope and spirit of the disclosed embodiments. The disclosed embodiments were chosen and described in order to best explain the principles of the invention and the practical application, and to enable others of ordinary skill in the art to understand the invention with various modifications as are suited to the particular use contemplated.

Therefore, disclosed above are embodiments of a back end of the line (BEOL) via farm interconnect structure on an integrated circuit chip. The BEOL via farm interconnect structure is reinforced to reduce the risk of delamination as a result of tensile stresses applied to the chip through lead-free C4 connections during thermal cycling (e.g., thermal cycling associated with flip-chip package assembly) and, thereby to reduce the risk of failure. Like conventional BEOL via farm interconnect structures, the reinforced BEOL via farm interconnect structure includes a plurality of vias electrically connecting metal wires within different wiring levels. However, reinforcement is added by incorporating dielectric columns into the lower metal wire so that the areas around the metal-to-metal interface between the vias and the lower metal wire contain a relatively strong dielectric-to-dielectric interface as opposed to a relatively weak dielectric-to-metal interface. The reinforced BEOL via farm interconnect structure can be located in an area of the integrated circuit chip at risk for delamination. Optionally, the reinforced BEOL via farm interconnect structure can have a reduced via density as compared to conventional BEOL via farm interconnect structures located in other areas of the chip in order to further reduce the risk of delamination. Also disclosed herein are embodiments of a method of forming a reinforced BEOL via farm interconnect structure on an integrated circuit chip and a method of redesigning an integrated circuit chip to include such reinforced BEOL via farm interconnect structure(s).

What is claimed is:

1. A reinforced interconnect structure on an integrated circuit chip, said reinforced interconnect structure comprising:
a first trench in a first dielectric layer;
a first metal layer within said first trench, said first dielectric layer having portions that extend vertically through a section of said first metal layer as columns;
at least one second dielectric layer above said first trench and having a lower portion and an upper portion above said lower portion;
a second trench in said upper portion;
a plurality of contact openings extending vertically from said second trench through said lower portion of said second dielectric layer to said section of said first metal layer, said contact openings being offset from said columns; and
a second metal layer within said second trench and said contact openings.

2. The reinforced interconnect structure of claim 1,
said first dielectric layer comprising an oxide layer, and
said at least one second dielectric layer comprising: a nitride layer above said first trench on said first metal layer and said columns; and another oxide layer on said nitride layer.

3. The reinforced interconnect structure of claim 1, said first metal layer and said second metal layer comprising copper.

4. The reinforced interconnect structure of claim 1, being located within an outer edge portion of said integrated circuit chip.

5. The reinforced interconnect structure of claim 1, further comprising a solder bump on said second metal layer.

6. The reinforced interconnect structure of claim 5, said solder bump being offset from said plurality of contact openings.

7. The reinforced interconnect structure of claim 1, being located within a predefined area extending between opposite corners of said integrated circuit chip.

8. A method of forming a reinforced interconnect structure on an integrated circuit chip, said method comprising:
forming a first trench in a first dielectric layer and further forming a first metal layer in said first trench such that said first dielectric layer has portions that extend vertically, as columns, through a section of said first metal layer;
forming at least one second dielectric layer above said first metal layer and said columns in said first trench;
forming a second trench in an upper portion of said second dielectric layer and a plurality of contact openings extending vertically from said second trench through a lower portion of said second dielectric layer to said section of first metal layer, said plurality of contact openings being offset from said columns; and
forming a second metal layer in said second trench and in said plurality of contact openings.

9. The method of claim 8, said first dielectric layer comprising an oxide layer and said forming of said at least one second dielectric layer comprising:
forming a nitride layer above said first trench on said first metal layer and said columns; and
forming another oxide layer on said nitride layer.

10. The method of claim 8, said forming of said first metal layer comprising performing a first electroplating process to form a first copper layer in said first trench and said forming of said second metal layer comprising performing a second electroplating process to form a second copper layer in said second trench and said plurality of contact openings.

11. The method of claim 8, said interconnect structure being formed within an outer edge portion of said integrated circuit chip.

12. The method of claim 8, further comprising forming a lead-free solder bump on said second metal layer.

13. The method of claim 8, said solder bump being formed so as to be offset from said plurality of contact openings.

14. The method of claim 8, said interconnect structure being formed within a predefined area extending between opposite corners of said integrated circuit chip.

15. A method of redesigning an integrated circuit chip, said method comprising:
receiving a design for said integrated circuit chip;
identifying at least one via farm interconnect structure in said design that, according to predefined rules, is at risk of failure, said at least one via farm interconnect structure comprising:
a first trench in a first dielectric layer;
a first metal layer within said first trench;
at least one second dielectric layer above said first trench and having a lower portion and an upper portion above said lower portion;
a second trench in said upper portion;
a plurality of contact openings extending vertically from said second trench through said lower portion of said second dielectric layer to a section of said first metal layer; and
a second metal layer within said second trench and said contact openings; and
altering said design so that said first dielectric layer further has portions that extend vertically through said section of said first metal layer as columns and so that said contact openings are offset from said columns.

16. The method of claim 15, said predefined rules specifying that any via farm interconnect structure in said design that is located within an outer edge portion of said integrated circuit chip is at risk of failure.

17. The method of claim 15, said predefined rules specifying that any via farm interconnect structure in said design that is located within an outer edge portion of said integrated circuit chip and in the highest wiring level of said integrated circuit chip is at risk of failure.

18. The method of claim 15, said predefined rules specifying that any via farm interconnect structure in said design that is not directly centered below a corresponding solder bump is at risk of failure.

19. The method of claim 15, said predefined rules specifying that any via farm interconnect structure in said design that is located within a predefined area extending between opposite corners of said integrated circuit chip is at risk of failure.

20. The method of claim 15, said altering further comprising identifying at least one redundant via in said via farm interconnect structure and removing said at least one redundant via from said design.
